(19) United States
(12) Patent Application Publication
(10) Pub. No.: US 2015/0160271 A1
(43) Pub. Date: Jun. 11, 2015

(54) CURRENT DETECTION DEVICE

(71) Applicant: Panasonic Intellectual Property Management Co., Ltd., Osaka (JP)

(72) Inventors: Hiroshi Yoshida, Osaka (JP); Masataka Kanda, Osaka (JP); Takuya Kagawa, Kyoto (JP); Kenji Okada, Osaka (JP); Atsushi Nakamura, Osaka (JP)

(21) Appl. No.: 14/413,648

(22) PCT Filed: Jun. 26, 2013
(86) PCT No.: PCT/JP2013/003979

§ 371 Date: Jan. 8, 2015

(30) Foreign Application Priority Data
Jul. 9, 2012 (JP) 2012-153728

(51) Int. Cl. G01R 19/00; G01R 33/06

(52) U.S. Cl. CPC G01R 19/0092; G01R 33/06

(57) ABSTRACT

A current detection device includes: a core to be disposed in the vicinity of a conductor as a detection target; a winding wound around the core; an excitation unit configured to apply an excitation signal, having a magnitude and a direction that change at a constant period, to the winding; a magnetic flux detection unit (comparator and averaging circuit) configured to detect a magnetic flux generated in the core due to current flowing through the conductor; and an adder unit configured to add a feedback signal to the excitation signal such that the magnetic flux detected by the magnetic flux detection unit is cancelled.

### TECHNICAL FIELD

The invention relates to a current detection device configured to detect current flowing through a conductor in a contactless manner.

### BACKGROUND ART

JP 2004-523909A (hereinafter referred to as Document 1) describes one kind of current detection devices. A conventional example described in Document 1 includes a transformer that has a probe core, a probe winding, a compensation core, a compensation winding, and the like. The probe winding is wound around the ring-shaped probe core, and the compensation winding is wound around both the probe core and the ring-shaped compensation core having a diameter larger than that of the probe core. A conductor, which is a measurement target, is disposed so as to pass through the probe core and the compensation core.

In this conventional example, the magnitude of current flowing through the conductor is detected by a known flux gate detection circuit. That is, this detection circuit includes a symmetry stage and an amplifier stage downstream from the former, and the symmetry stage is connected at an input side to the probe winding. Bipolar magnetization is induced in the probe core via the symmetry stage. In this stage, an output signal generated from the asymmetry of the voltage and/or current characteristics over time is amplified in the amplifier stage and is used for controlling the compensation winding. The output current of the amplifier stage is fed into the compensation winding across a resistor (e.g., leading to ground potential). In the regulated state, the field of this current in the compensation core and in the probe core compensates for the magnetic flux of the conductor. Then the output current of the amplifier stage and thus the voltage drop across the resistor are proportional to the primary current flowing through the conductor. Accordingly, the magnitude of current flowing through the conductor can be detected by measuring the voltage drop across the resistor.

However, there is a problem in that the conventional example described in Document 1 has a complicated structure and downsizing thereof is difficult, since the transformer is constituted by two cores (the probe core and the compensation core) and two windings (the probe winding and the compensation winding). Also, there is a problem in that, although the magnitude of AC current flowing through the conductor can be detected by detecting the voltage induced in the compensation winding, the excitation current flowing through the probe winding affects the accuracy of current detection. Furthermore, there is a problem in that the compensation core is magnetized when an excessive current flows through the conductor, and thereafter the accuracy of current detection thereafter is influenced.

### SUMMARY OF INVENTION

The present invention has been made in view of the above-described problems, and an object of the present invention is to provide a current detection device that is downsized compared with the conventional example and has the improved accuracy of current detection and the improved stability with respect to overcurrent.

A current detection device according to the present invention includes: a core to be disposed in a vicinity of a conductor which is a detection target; a winding wound around the core; an excitation unit configured to apply an excitation signal, having a magnitude and a direction that change at a constant period, to the winding; a magnetic flux detection unit configured to detect a magnetic flux generated in the core due to current flowing through the conductor; and an adder unit configured to add a feedback signal for cancelling the magnetic flux, which is detected by the magnetic flux detection unit, to the excitation signal.

It is preferable that, in the current detection device, the excitation unit is configured to magnetically saturate the core by applying the excitation signal, having a waveform which is symmetric in positive and negative, to the winding, and the magnetic flux detection unit includes a comparator configured to compare the excitation signal (an output from the winding) with threshold values that have the same absolute value but different signs, and an averaging circuit configured to average an output of the comparator in time axis over one period of the excitation signal, and is configured to generate the feedback signal from an output of the averaging circuit.

It is preferable that, in the current detection device, the threshold values of the comparator are variable.

It is preferable that, in the current detection device, the excitation unit is configured to apply the excitation signal, having a waveform which is symmetric in positive and negative, to the winding, and the magnetic flux detection unit includes an effective value calculation circuit configured to calculate an effective value of the excitation signal (an output from the winding), and is configured to generate the feedback signal from the effective value calculated in the effective value calculation circuit.

It is preferable that, in the current detection device, the excitation unit is configured to apply the excitation signal, having a waveform which is symmetric in positive and negative, to the winding, and the magnetic flux detection unit includes an averaging circuit configured to average the excitation signal (an output from the winding) in time axis over one period of the excitation signal, and is configured to generate the feedback signal from an output of the averaging circuit.

It is preferable that, in the current detection device, the excitation unit is configured so that the timing at which the excitation signal takes a peak value approximately matches with the timing at which the core is magnetically saturated.

It is preferable that the current detection device further includes a detection unit configured to detect a level of the feedback signal.

It is preferable that, in the current detection device, the detection unit is connected between the magnetic flux detection unit and the adder unit.

It is preferable that the current detection device further includes a detection unit configured to detect an output level of the magnetic flux detection unit.

It is preferable that, in the current detection device, the detection unit is connected between the magnetic flux detection unit and ground.

It is preferable that the current detection device further includes a low pass filter that is connected between the magnetic flux detection unit and the detection unit.

It is preferable that, in the current detection device, the core is formed of soft magnetic material.

It is preferable that, in the current detection device, the core is formed in a ring shape through which the conductor passes.

It is preferable that, in the current detection device, the core is an assembly of detachable divided components.

It is preferable that, in the current detection device, the core is formed in a columnar shape.

The current detection device according to the present invention includes: the magnetic flux detection unit configured to detect the magnetic flux generated in the core due to the current flowing through the conductor; and the adder unit configured to add a feedback signal to the excitation signal such that the magnetic flux detected by the magnetic flux detection unit is cancelled by the feedback signal, and accordingly has an effect that the size thereof can be reduced compared with the conventional example that includes two cores and two windings, and the accuracy of current detection and the stability with respect to overcurrent can be improved.

### BRIEF DESCRIPTION OF DRAWINGS

FIG. 1 is a circuit configuration diagram illustrating a current detection device according to an embodiment of the present invention;

FIGS. 2A to 2D are waveform diagrams for illustrating operations of the current detection device;

FIG. 3 includes an upper waveform diagram of a signal voltage (an excitation voltage) of an excitation signal, and a lower waveform diagram of a signal current (an excitation current) of the excitation signal of the current detection device;

FIGS. 4A to 4E are perspective views illustrating other configurations of the core in the current detection device;

FIG. 5 is a block diagram illustrating a current detection device according to another embodiment of the present invention;

FIG. 6 is a circuit configuration diagram illustrating a current detection device according to yet another embodiment of the present invention;

FIG. 7 is a circuit configuration diagram illustrating a current detection device according to yet another embodiment of the present invention; and

FIGS. 8A and 8B are block diagrams illustrating another configuration of an excitation unit in the current detection device according to the present invention.

### DESCRIPTION OF EMBODIMENTS

Hereinafter, embodiments of a current detection device according to the present invention will be described in detail with reference to the diagrams.

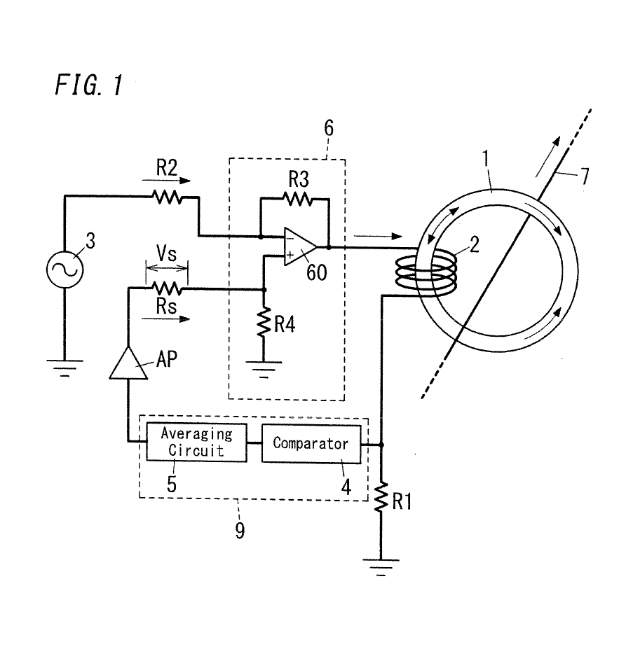

The current detection device according to one embodiment includes a core 1, a winding 2 that is wound around the core 1, an excitation unit 3, a comparator 4, an averaging circuit 5, an adder unit 6, and the like, as shown in FIG. 1.

The core 1 is formed of soft magnetic material in a circular ring shape through which a conductor 7, as a detection target, passes. The soft magnetic material that forms the core 1 is preferably nanocrystal material, amorphous metal material (such as amorphous ribbon or amorphous wire), ferrite, magnetic fluid, or the like. The nanocrystal material and the amorphous metal material have an advantage that a hysteresis loop is maintained up to a high frequency, and the amorphous metal material is superior in strength over the nanocrystal material. Also, the ferrite has a feature that the cost is lower than the nanocrystal material and the amorphous metal material, and the magnetic fluid has a feature of not having hysteresis.

The winding 2 that is wound around the core 1 has one end connected to the adder unit 6 (an output end thereof) and the other end connected to ground via a resistor R1.

The excitation unit 3 is configured to output an excitation signal having a waveform of which the magnitude and direction change at a constant period and which is symmetric in positive and negative (such as sine wave, square wave, or triangular wave). The excitation unit 3 is configured to output an excitation voltage having a waveform which is symmetric in positive and negative. A positive electrode of the excitation unit 3 is connected to a first input end of the adder unit 6 via a current limiting resistor R2, and a negative electrode of the excitation unit 3 is grounded.

The comparator 4 is configured to compare threshold values that have the same absolute value but different signs with the excitation signal (a voltage drop across the resistor R1 that is proportional to the excitation signal, in actuality). That is, the comparator 4 is configured to compare the threshold values that have the same absolute value but different signs and the output from the winding 2. The comparator 4 is configured to compare the excitation signal (the output from the winding 2) with the threshold values ±Th. The comparator 4 is configured to output a high level (H) signal in a first period which is a period from a time point when the excitation signal rises to reach the threshold value Th to a time point when the excitation signal falls to reach the threshold value −Th after that, and a low level (L) signal in a second period which is a period from a time point when the excitation signal falls to reach the threshold value −Th to a time point when the excitation signal rises to reach the threshold value Th after that. The comparator 4 includes a window comparator, for example, and is configured to switch the output thereof between the high level and the low level at every falling edge of the output from the window comparator. The averaging circuit 5 is configured to calculate a time average of the output of the comparator 4 over a period of the excitation signal, and is constituted by an integration circuit, for example. The comparator 4 and the averaging circuit 5 constitute a magnetic flux detection unit 9 in the present embodiment. The output from the averaging circuit 5 is, after being amplified by an amplifier AP, inputted to a second input end of the adder unit 6 via the detection resistor Rs.

The adder unit 6 is constituted by an inverting amplifier that includes an operational amplifier 60, a feedback resistor R3, and an input resistor R4. The adder unit 6 is configured to add the output from the averaging circuit 5, which is inputted via the detection resistor Rs, to the excitation signal that is outputted from the excitation unit 3, and to output the added result to the winding 2.

Next, operations of the current detection device according to the present embodiment will be described.

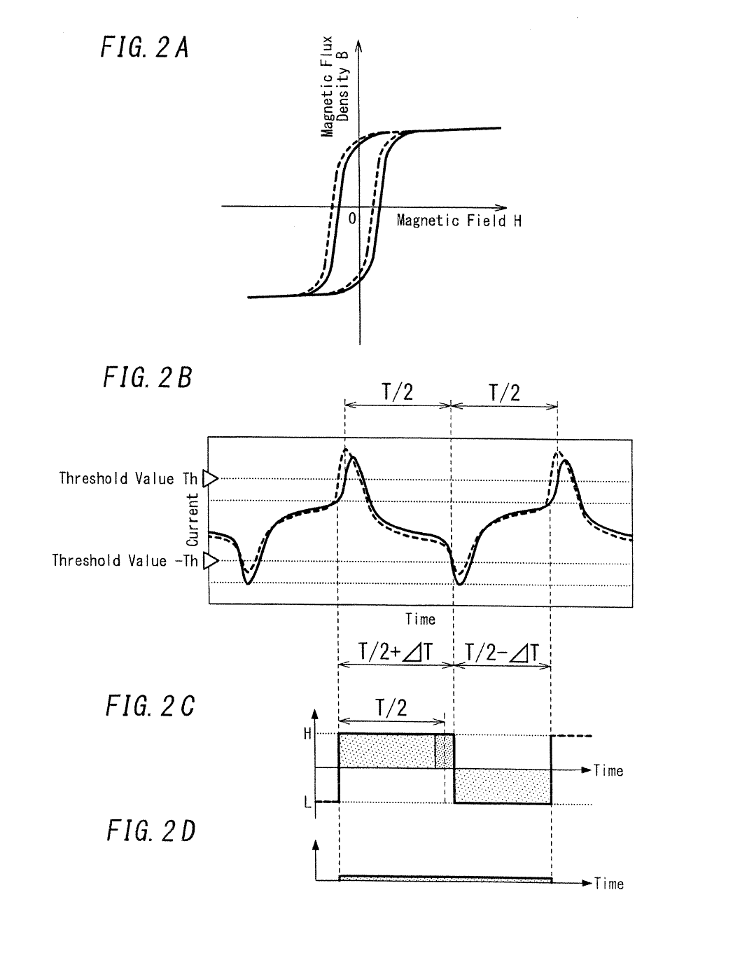

A magnetic flux (a magnetic field) is generated in the core 1 when the excitation signal (an excitation current) flows through the winding 2. The direction and magnitude of the magnetic flux change in synchronization with those of the excitation signal. That is, when no current flows through the conductor 7, the magnetic flux in the core 1 includes only the magnetic flux generated due to the excitation signal flowing through the winding 2, and therefore the magnetization characteristic (B-H characteristic) of the core 1 shows a loop that is point symmetrical relative to the origin, as shown by the solid line in FIG. 2A.

In this regard, the current detection device of the present embodiment adopts a flux gate magnetic flux detection method, and is configured to magnetically saturate the core 1 to rapidly change the excitation signal (the excitation current), and to detect the timing at which the excitation current changes rapidly by the comparator 4 (refer to the waveform shown by the solid line in FIG. 2B). With regard to a period T of the excitation signal, when no current flows through the conductor 7, a time period during which the output of the comparator 4 is the high level and a time period during which the output of the comparator 4 is the low level are both T/2. Accordingly, the output of the averaging circuit 5 is zero, and nothing is added to the excitation signal.

On the other hand, when current flows through the conductor 7, a magnetic flux (a magnetic field) is generated in the core 1 that is arranged in the periphery of the conductor 7, where the direction of the magnetic flux follows the Ampere's law. Accordingly, the magnetization characteristic of the core 1 changes, and shows a loop that is not point symmetrical relative to the origin, as shown by the broken line in FIG. 2A. Therefore, a time period difference ΔT occurs between the time period during which the output of the comparator 4 is the high level and the time period during which the output thereof is the low level. In this case, for example, the time period during which the output of the comparator 4 is the high level is T/2+ΔT and the time period during which the output thereof is the low level is T/2−ΔT (refer to FIG. 2C). As a result, the output of the averaging circuit 5 is not zero, and takes a level according to the time difference ΔT (refer to FIG. 2D).

Then, the output of the averaging circuit 5, after being amplified in the amplifier AP, is added, in the adder unit 6, to the excitation signal that is outputted from the excitation unit 3. In this regard, the adder unit 6 is configured to invert the output of the averaging circuit 5, and then add the inverted result to the excitation signal that is outputted from the excitation unit 3. Therefore, the excitation signal is subjected to a feedback (negative feedback) that leads the time difference ΔT to zero, as a result of the addition of the output of the averaging circuit 5 to the excitation signal. Accordingly, by detecting the level of the output (the feedback signal) of the averaging circuit 5 as a voltage (a voltage drop) Vs across the detection resistor Rs when the time difference ΔT is considered to be zero, the magnitude of the current flowing through the conductor 7 can be calculated from the level of the feedback signal. Note that by making the threshold value Th of the comparator 4 variable, the sensitivity of current detection can be adjusted.

The output of the magnetic flux detection unit 9 (the output of the averaging circuit 5) is detected as the voltage (the voltage drop) Vs across the detection resistor (a detection unit) Rs. The current detection device according to the present embodiment can detect DC current or AC current having a frequency that is of approximately the same order as the excitation signal (having a frequency that is smaller than the frequency of the excitation signal), flowing through the conductor 7.

As described above, the current detection device according to the present embodiment includes the magnetic flux detection unit 9 (the comparator 4 and the averaging circuit 5) configured to detect the magnetic flux generated in the core 1 due to current flowing through the conductor 7, and the adder unit 6 configured to add the feedback signal to the excitation signal such that the magnetic flux detected in the magnetic flux detection unit 9 is cancelled. Accordingly, the current detection device can be downsized compared with the conventional example described in Document 1 (hereinafter referred to as the conventional example) that needs two cores and two windings, since the current detection device needs only one core and one winding. Also, the detection accuracy is decreased in the conventional example since excitation noise that is caused by the two windings being magnetically coupled is superimposed in the output. In contrast, the current detection accuracy can be improved in the current detection device according to the present embodiment compared with the conventional example since only one winding 2 is included in the present embodiment. Furthermore, unlike the conventional example, the present embodiment does not include a core that is not magnetically saturated, and accordingly the stability with respect to an overcurrent of the current flowing through the conductor 7 can be improved compared with the conventional example.

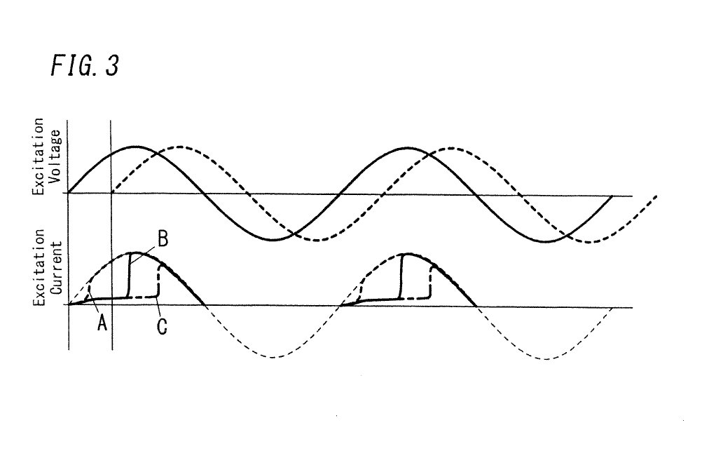

Incidentally, in order to improve the signal to noise ratio of the feedback signal by suppressing the influence of the noise component that is superimposed on the excitation signal, it is desirable that the timing at which the excitation signal (the excitation current) takes a peak value approximately matches with the timing at which the core 1 is magnetically saturated, as shown by the solid line B in the lower part of FIG. 3. According to this case, the variation amount of the excitation current increases compared with a case in which the timing at which the excitation current takes a peak value is earlier than the timing at which the core 1 is magnetically saturated (as shown by the broken line A in FIG. 3), and a case in which the timing at which the excitation current takes a peak value is later than the timing at which the core 1 is magnetically saturated (as shown by the dashed-dotted line C in FIG. 3). As a result, an erroneous determination due to the noise component is unlikely to occur when the comparator 4 performs the comparison with respect to the threshold values, resulting in an improvement in the signal to noise ratio of the feedback signal. In order to approximately match the timing at which the core 1 is magnetically saturated and the timing at which the excitation current takes a peak value, it is sufficient that the signal voltage of the excitation signal that is outputted from the excitation unit 3 or the number of turns of the winding 2 is adjusted according to the magnetization characteristic of the core 1.

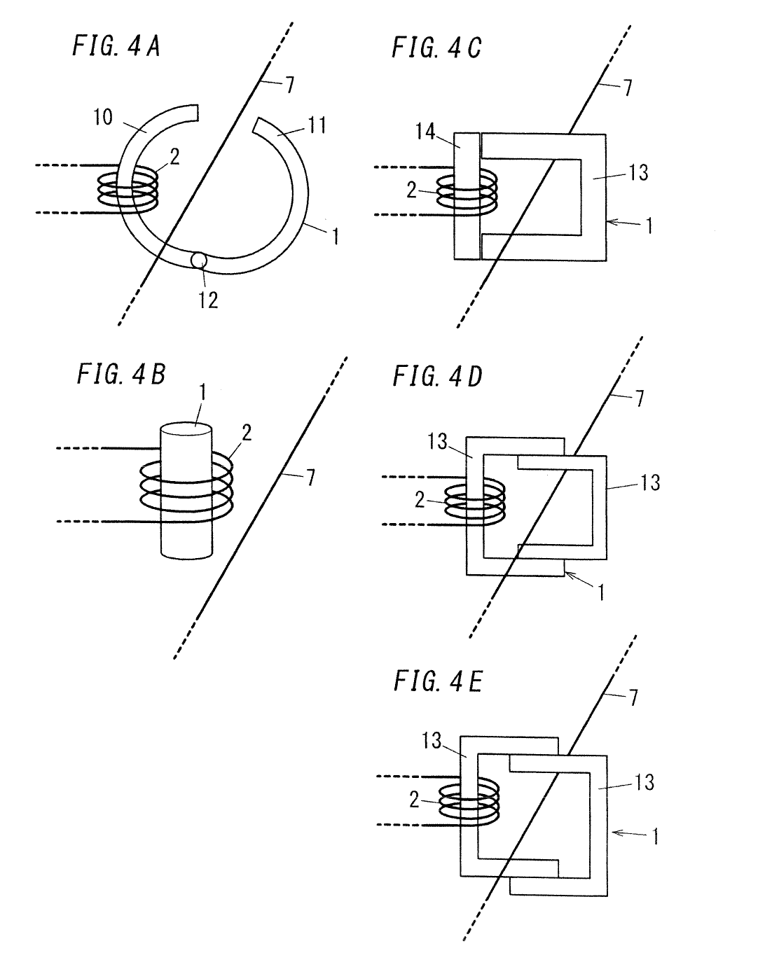

Here, it is preferable that the core 1 is divided into two semi-circular portions 10 and 11, as shown in FIG. 4A, ends of the portions 10 and 11 on one side are rotatably coupled by a shaft 12, and the other ends (free ends) of the portions 10 and 11 on the other side are detachable from each other. The conductor 7, as a detection target, can be easily passed through the core 1 having such a structure.

Alternatively, the core 1 may be formed in a columnar shape (a circular cylinder, for example), as shown in FIG. 4B. The winding 2 can be easily wound around the core 1 having such a columnar shape.

Also, the shape of the core 1 is not limited to a circular ring, and the core 1 may have a rectangular frame shape in which a substantially C-shaped (a bracket-shaped) core 13 and an I-shaped core 14 are combined, as shown in FIG. 4C, for example. Alternatively, the core 1 may be configured by combining two substantially C-shaped cores 13, as shown in FIGS. 4D and 4E.

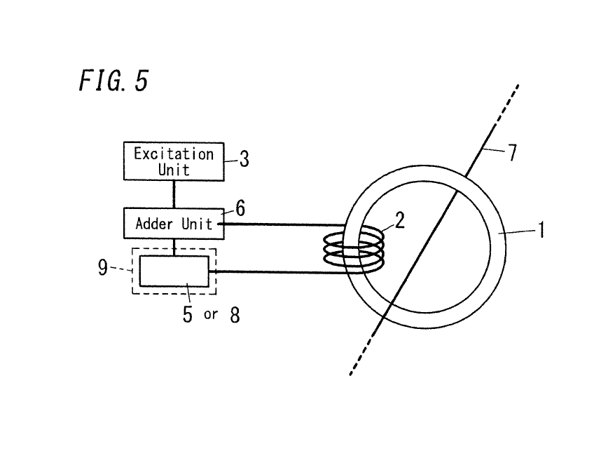

Incidentally, in the above embodiment, the case where the magnetic flux detection unit 9 is constituted by the comparator 4 and the averaging circuit 5 was taken as an example. However, a magnetic flux detection unit 9 may be constituted by only an averaging circuit 5 configured to calculate a time average of an excitation signal over a period of the excitation signal, as shown in FIG. 5. In this case, a feedback signal may be generated from the output of the averaging circuit 5. Alternatively, a magnetic flux detection unit 9 may be constituted by an effective value calculation circuit 8 configured to calculate an effective value of an excitation signal, instead of the averaging circuit 5. In this case, a feedback signal may be generated from the effective value that is calculated by the effective value calculation circuit 8. Since the effective value calculation circuit 8 can be realized by a known technique, detailed illustration and description of the circuit configuration thereof will be omitted.

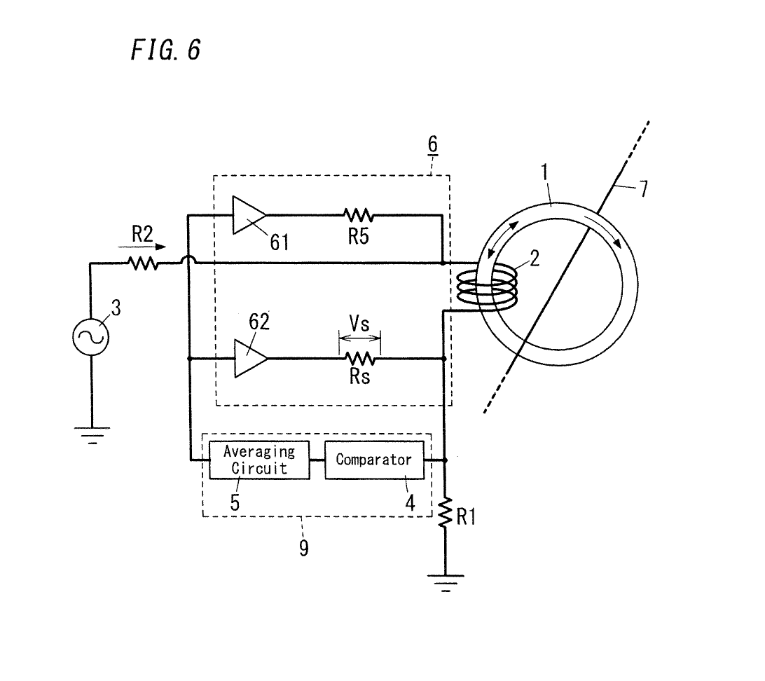

Also, the configuration of the adder unit 6 is not limited to the inverting amplifier including the operational amplifier 60. For example, an adder unit 6 may include two amplifiers 61 and 62 of which respective output ends are bridge-connected via a winding 2, as shown in FIG. 6. In this example, a resistor R5 is connected to an output end of one amplifier 61, and a detection resistor Rs is connected to an output end of the other amplifier 62. Accordingly, the outputs (feedback signals) of the amplifiers 61 and 62 are added to the excitation signal via the resistor R5 and the detection resistor Rs, respectively, and the resultant signal is applied to the winding 2. According to such a circuit configuration, there is an advantage that the output voltage of the adder unit 6 is doubled compared with a case of one amplifier.

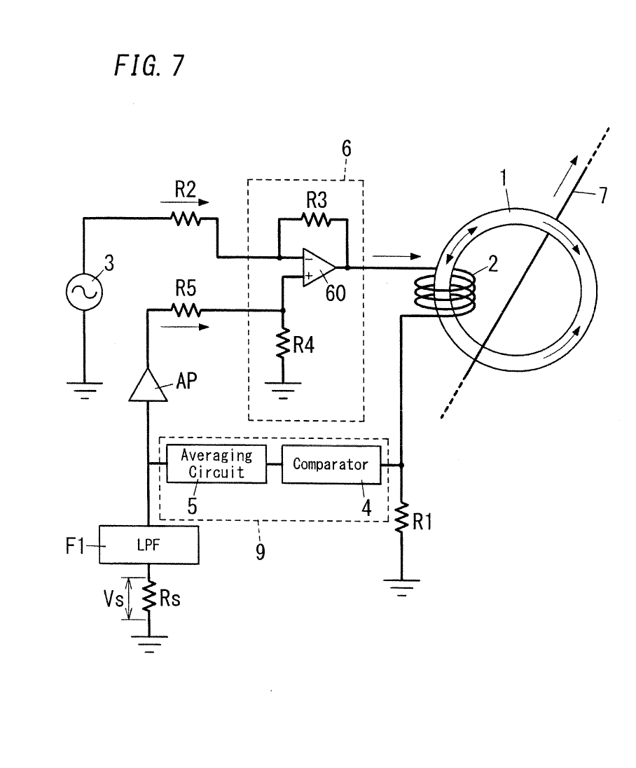

Also, the detection resistor Rs (a detection unit) may be connected between the magnetic flux detection unit 9 and ground, as shown in FIG. 7. The output of the magnetic flux detection unit 9 is, after being amplified by the amplifier AP, inputted to a second input end of the adder unit 6 via a resistor R5.

Also, it is preferable that a low pass filter F1 is disposed between a magnetic flux detection unit 9 and a detection resistor Rs (a detection unit). By the low pass filter F1 provided on an input side of the detection resistor Rs, a high frequency noise component is reduced, and as a result, the accuracy of detection of the output from the magnetic flux detection unit 9 can be improved.

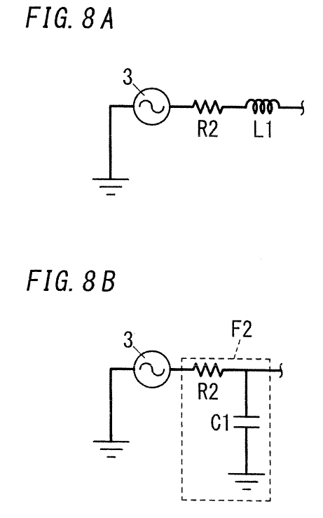

Also, as shown in FIGS. 8A and 8B, an impedance element (an inductor L1) or a low pass filter F2 (a resistor R2 connected in series to an excitation unit 3 and a capacitor C1 connected in parallel to the excitation unit 3) may be provided between the excitation unit 3 and an adder unit 6. According to such a configuration, in the case where the excitation signal is a square wave or the like, the waveform of the excitation signal is rounded by removing a high frequency component thereof, and as a result, a sharp change of the excitation signal can be eliminated and noise generated in the adder unit 6 and the like can be reduced.

1. A current detection device comprising:
a core to be disposed in a vicinity of a conductor as a detection target;
a winding wound around the core;
an excitation unit configured to apply an excitation signal, having a magnitude and a direction that change at a constant period, to the winding;
a magnetic flux detection unit configured to detect a magnetic flux generated in the core due to current flowing through the conductor; and
an adder unit configured to add a feedback signal to the excitation signal such that the magnetic flux detected by the magnetic flux detection unit is cancelled.

2. The current detection device according to claim 1, wherein
the excitation unit is configured to magnetically saturate the core by applying the excitation signal, having a waveform which is symmetric in positive and negative, to the winding, and
the magnetic flux detection unit comprises a comparator configured to compare the excitation signal with threshold values that have the same absolute value but different signs, and an averaging circuit configured to calculate a time average of an output of the comparator over the period of the excitation signal, and is configured to generate the feedback signal from an output of the averaging circuit.

3. The current detection device according to claim 2, wherein the threshold values of the comparator are variable.

4. The current detection device according to claim 1, wherein
the excitation unit is configured to apply the excitation signal, having a waveform which is symmetric in positive and negative, to the winding, and
the magnetic flux detection unit comprises an effective value calculation circuit configured to calculate an effective value of the excitation signal, and is configured to generate the feedback signal from the effective value calculated in the effective value calculation circuit.

5. The current detection device according to claim 1, wherein
the excitation unit is configured to apply the excitation signal, having a waveform which is symmetric in positive and negative, to the winding, and
the magnetic flux detection unit comprises an averaging circuit configured to calculate a time average of the excitation signal over the period of the excitation signal, and is configured to generate the feedback signal from an output of the averaging circuit.

6. The current detection device according to claim 1, wherein the excitation unit is configured so that the timing at which the excitation signal takes a peak value approximately matches with the timing at which the core is magnetically saturated.

7. The current detection device according to claim 1, further comprising a detection unit configured to detect a level of the feedback signal.

8. The current detection device according to claim 7, wherein the detection unit is connected between the magnetic flux detection unit and the adder unit.

9. The current detection device according to claim 1, further comprising a detection unit configured to detect an output level of the magnetic flux detection unit.

10. The current detection device according to claim 9, wherein the detection unit is connected between the magnetic flux detection unit and ground.

11. The current detection device according to claim 10, further comprising a low pass filter that is connected between the magnetic flux detection unit and the detection unit.

12. The current detection device according to claim 1, wherein the core is formed of soft magnetic material.

13. The current detection device according to claim 1, wherein the core is formed in a ring shape through which the conductor passes.

14. The current detection device according to claim 13, wherein the core is an assembly of detachable divided components.

15. The current detection device according to claim 1, wherein the core is formed in a columnar shape.
